(19) United States
(12) Patent Application Publication
(10) Pub. No.: US 2023/0051442 A1
(43) Pub. Date: Feb. 16, 2023

(54) Method for Calibrating Crosstalk Errors in System for Measuring on-Wafer S Parameters and Electronic Device

(71) Applicant: THE 13TH RESEARCH INSTITUTE OF CHINA ELECTRONICS TECHNOLOGY GROUP CORPORATION, Shijiazhuang (CN)

(72) Inventors: Aihua Wu, Shijiazhuang (CN); Xingchang Fu, Shijiazhuang (CN); Yuan Fang, Shijiazhuang (CN); Yibang Wang, Shijiazhuang (CN); Ye Huo, Shijiazhuang (CN); Faguo Liang, Shijiazhuang (CN); Chen Liu, Shijiazhuang (CN); Peng Luan, Shijiazhuang (CN); Senfeng Xu, Shijiazhuang (CN); Xiaohua Chen, Shijiazhuang (CN); Xiaoyun Zhang, Shijiazhuang (CN)

(21) Appl. No.: 17/890,854

(22) Filed: Aug. 18, 2022

Related U.S. Application Data
(63) Continuation of application No. PCT/CN2022/081431, filed on Mar. 17, 2022.

(30) Foreign Application Priority Data
Aug. 16, 2021 (CN) 202110938374.8

(51) Int. Cl. G01R 35/00; G01R 31/28

(52) U.S. Cl. CPC G01R 35/005; G01R 31/2851

(57) ABSTRACT

A method for calibrating crosstalk errors in a system for measuring on-wafer S parameters and an electronic device are provided. The method includes two parts. The first part is the pre-calibration part, which obtain eight error terms of an on-wafer S parameter measurement system by using a thru calibration standard, two defined load calibration standards, two pairs of undefined reflect calibration standards, and the reciprocity properties of a passive reciprocal element. The first part performs pre-calibration on an uncalibrated system according to the eight error terms. The second part uses the pre-calibrated system to obtain the crosstalk errors of the measurement system, and performs a further calibration on the pre-calibrated system according to the crosstalk errors.

### CROSS-REFERENCE TO RELATED APPLICATIONS

This application is a continuation application of International Application No. PCT/CN2022/081431, filed on Mar. 17, 2022, which claims priority to Chinese Patent Application No. CN 202110938374.8, filed on Aug. 16, 2021. The disclosures of the aforementioned applications are hereby incorporated herein by reference in their entireties.

### TECHNICAL FIELD

The present application relates to the technical field of on-wafer S parameter calibration, and in particular, to a method for calibrating crosstalk errors in a system for measuring on-wafer S parameters and an electronic device.

### BACKGROUND

On-wafer S-parameter measurement systems (e.g., Vector Network Analyzers) are generally used in the microelectronics industry. Before each use of a measurement system, it is necessary to select an appropriate calibration method to pre-calibrate the measurement system. The pre-calibration methods in the prior art mainly include SOLT (Short-Open-Load-Thru) method, LRM (Line-Reflect-Match) method, LRRM (Line-Reflect-Reflect-Match) method and TRL (Thru-Reflect-Line) calibration method, etc.

With the increase of the on-wafer measurement frequency, some systematic errors that can be ignored in the low frequency band will gradually increase. Especially, the crosstalk errors will become larger and larger, which will lead to inaccurate measurement results. Crosstalk errors can be errors due to coupling between two probes of the measurement system. During measurement, the electromagnetic energy is not only transmitted from one probe to another probe through a DUT (Device Under Test), but also part of the electromagnetic energy is transmitted through the air and the substrate of the DUT. The transfer of electromagnetic energy through the air and the substrate is a detriment to the measurement, resulting in crosstalk errors. Therefore, after the pre-calibration mentioned above, a crosstalk error calibration is performed on the pre-calibrated system to make the measurement results more accurate.

The SOLT method in the prior uses an eight-term error model and requires four calibration standards: Short, Open, Load, and Reciprocity. A “calibration standard” is a physical element measured by an S-parameter measurement system in a calibration process. The parameters of the Short, Open and Load calibration standards need to be known (i.e., need to be defined) before measurement that cause at least two problems. The first problem is it have to spend costs to obtain the parameters of the calibration standards. The second problem is the more parameters that need to be obtained, the greater the possibility of inaccurate parameters. The inaccurate parameters will greatly adversely affect the calibration accuracy of the on-wafer S parameter measurement system.

### SUMMARY

These and other problems are generally solved or circumvented, and technical advantages are generally achieved, by embodiments of the present application which provide a method for calibrating crosstalk errors in a system for measuring on-wafer S parameters and an electronic device.

### Technical Problems

The present application provides a method for calibrating crosstalk errors in a system for measuring on-wafer S parameters and an electronic device and intends to solve the technical problem that the SOLT calibration method in the prior art has high costs and low accuracy.

### Technical Solutions

In a first aspect, the present application provides a method for calibrating crosstalk errors in a system for measuring on-wafer S parameters, and the method includes two parts.

The first part is the pre-calibration part, which obtain eight error terms of an on-wafer S parameter measurement system by using a thru calibration standard, two load calibration standards, two pairs of reflect calibration standards, and the reciprocity properties of a passive reciprocal element. According to the eight error terms, the on-wafer S parameter measurement system is pre-calibrated. The first part includes a first measuring step, a first calculating step and a first calibrating step. The first measuring step uses the on-wafer S parameter measurement system to measure the thru calibration standard, the two load calibration standards and the two pairs of reflect calibration standards, respectively, to obtain thru S parameters of the thru calibration standard, load S parameters of the two load calibration standards and reflect S parameters of the two pairs of reflect calibration standards. The two pairs of reflect calibration standards include a pair of undefined and identical open calibration standards and a pair of undefined and identical short calibration standards. The reflect S parameters include open S parameters corresponding to the pair of open calibration standards and the short S parameters corresponding to the pair of short calibration standards. Besides, a pair of reflect calibration standards can be saved if the two load calibration standards are exactly the same. The first calculating step calculates the eight error terms of the measurement system according to the thru S parameters, the load S parameters, the open S parameters, the short S parameters, a proportional coefficient and a correspondence between transfer parameter and S parameter. The proportional coefficient can be obtained by measuring a passive reciprocal element. The passive reciprocal element may be the pair of open calibration standards, the pair of short calibration standards or the two load calibration standards.

The correspondence between transfer parameter and S parameter is known in the art. The first calibrating step pre-calibrates the measurement system according to the eight error terms and obtains a pre-calibrated system.

The second part uses the pre-calibrated system to obtain the crosstalk errors of the measurement system, and performs a further calibration on the pre-calibrated system according to the crosstalk errors. The second part includes a simulating step, a second measuring step, a second calculating step and a second calibrating step. The simulating step simulates a crosstalk calibration standard to obtain real S parameters of the crosstalk calibration standard. The pair of open calibration standards mentioned above can be used as crosstalk calibration standard here. The second measuring step measures the crosstalk calibration standard by using the pre-calibrated system to obtain crosstalk S parameters of the crosstalk calibration standard that includes crosstalk errors of the measurement system. The second calculating step calculates the crosstalk errors according to the real S parameters, the crosstalk S parameters and a conversion relationship between Y parameter and S parameter. The conversion relationship between Y parameter and S parameter is known in the art. The second calibrating step final-calibrates the measurement system according to the crosstalk errors.

In a second aspect, the present application provides an electronic device including a non-transitory memory and a processor. The non-transitory memory stores a computer executable program. The processor is configured to execute the program to implement the method for calibrating crosstalk errors in a system for measuring on-wafer S parameters mentioned above.

In a third aspect, the present application provides a non-transitory computer readable storage medium storing a computer executable program. When the computer executable program is executed by a processor, the method for calibrating crosstalk errors in a system for measuring on-wafer S parameters is implemented.

In a fourth aspect, the present application provides a calibrating device including several executing modules capable of implementing the steps of the method for calibrating crosstalk errors in a system for measuring on-wafer S parameters mentioned above.

### Advantageous Effects of the Disclosure

Compared with the SOLT calibration method in the prior art, the advantageous effects of the method calibrating crosstalk errors in a system for measuring on-wafer S parameters provided by the present application are as follows: the method provided by the present application uses a thru calibration standard, two load calibration standards, two pairs of reflect calibration standards to obtain the eight terms errors of the on-wafer S parameter measurement system. When measures the thru calibration standard, the measurement system is calibrated to a center of the thru calibration standard. In this case, the thru S parameters are known, i.e., the thru calibration standard is defined. That is, it doesn't need to spend costs to define the thru calibration standard. For the pair of reflect calibration standards, because they are identical and have symmetry, their actual parameters can be cancelled out in the calculation process of the method provided in the present application. That is, the reflect calibration standards can be undefined. The calculation process of the method also uses the reciprocity of the passive reciprocal element, i.e., when the passive reciprocal element is measured as a two ports element, S21=S12. In summary, among the calibration standards mentioned above, only the two load calibration standards need to be defined, and for all the other calibration standards, there is no need to spend costs to define them. Therefore, the method provided by the present application can reduce costs and improve efficiency. After the eight error terms of the measurement system are obtained, the crosstalk errors of the measurement system are further obtained by using the crosstalk calibration standard, so as to realize the final calibration of the measurement system. The final-calibrated system can achieve the expected measurement accuracy. Because requiring fewer defined calibration standards, the method provided by the present application can reduce the adverse influence of the inaccurate definition of the calibration standards and improve the calibration precision, so that the final-calibrated on-wafer S-parameter measurement system has higher measurement accuracy.

### BRIEF DESCRIPTION OF THE DRAWINGS

In order to more clearly illustrate the technical solutions in the embodiments of this application, the accompanying drawings to be used in the descriptions of the embodiments or the prior art will be briefly described below. Obviously, the accompanying drawings in the following description are only some embodiments of this application, and for a person of ordinary skill in the art, without involving any inventive effort, other accompanying drawings may also be obtained according to these accompanying drawings.

FIG. 1 is a flow diagram of the method for calibrating crosstalk errors in a system for measuring on-wafer S parameters according to embodiments of the present application;

FIG. 2 is a schematic diagram of a crosstalk error model in the prior art;

FIG. 3 is a schematic diagram of eight term error model in the prior art;

FIG. 4 is a schematic diagram of the relationship between transfer parameters and voltage and current in the prior art;

FIG. 5 is a comparison diagram of two results that obtained by two on-wafer S parameter measurement system, where the two measurement systems are calibrated by the multi-line TRL calibration method in the prior art and the calibration method provided by the present application;

FIG. 6 is a schematic structural diagram of the calibrating device according to embodiments of the present application; and

FIG. 7 is a schematic structural diagram of the electronic device according to embodiments of the present application.

### DETAILED DESCRIPTION OF ILLUSTRATIVE EMBODIMENTS

In the following description, for the purpose of illustration rather than limitation, specific details such as a specific system structure and technology are set forth in order to provide a thorough understanding of the embodiments of the present application. However, it will be apparent to those skilled in the art that the present application may be practiced in other embodiments without these specific details. Detailed descriptions of well-known systems, devices, circuits, and methods are omitted so as not to obscure the description of the present application with unnecessary detail.

In order to make the technical problems to be solved by the present application, technical solutions and advantageous effects clearer, the present application will be further described in detail below with reference to the accompanying drawings and embodiments.

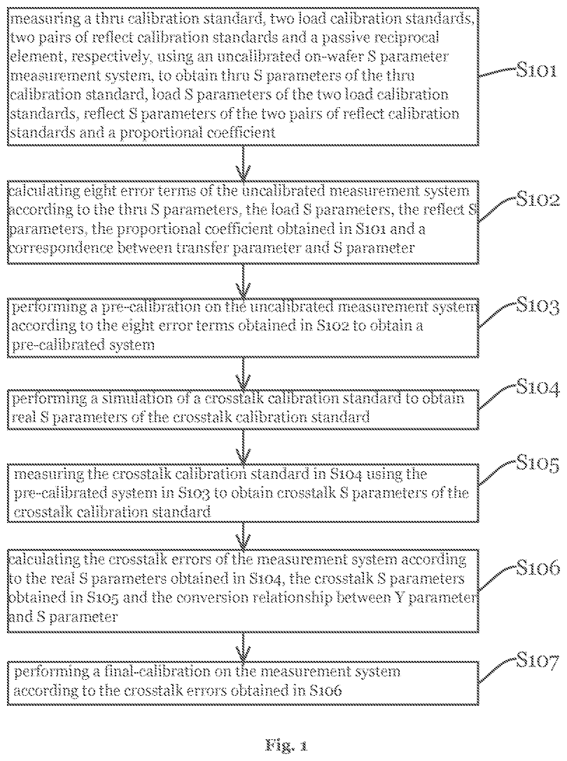

As show in FIG. 1, in one embodiment of the present application, the method for calibrating crosstalk errors in a system for measuring on-wafer S parameters include the following steps:

S101: measuring a thru calibration standard, two load calibration standards, two pairs of reflect calibration standards and a passive reciprocal element, respectively, using an uncalibrated on-wafer S parameter measurement system, to obtain thru S parameters of the thru calibration standard, load S parameters of the two load calibration standards, reflect S parameters of the two pairs of reflect calibration standards and a proportional coefficient;
S102: calculating eight error terms of the uncalibrated measurement system according to the thru S parameters, the load S parameters, the reflect S parameters, the proportional coefficient obtained in S101 and a correspondence between transfer parameter and S parameter, where the symmetry of the reflect calibration standards and the reciprocal properties of the passive reciprocal element will be used in the calculation process;
S103: performing a pre-calibration on the uncalibrated measurement system according to the eight error terms obtained in S102 to obtain a pre-calibrated system;
S104: performing a simulation of a crosstalk calibration standard to obtain real S parameters of the crosstalk calibration standard;
S105: measuring the crosstalk calibration standard in S104 using the pre-calibrated system in S103 to obtain crosstalk S parameters of the crosstalk calibration standard, where the crosstalk S parameters contains crosstalk errors of the measurement system and the crosstalk errors can be equivalent to a microwave circuit network in parallel with the crosstalk calibration standard;
S106: calculating the crosstalk errors of the measurement system according to the real S parameters obtained in S104, the crosstalk S parameters obtained in S105 and the conversion relationship between Y parameter and S parameter; and
S107: performing a final-calibration on the measurement system according to the crosstalk errors obtained in S106.

S101 to S107 will be further described below.

1. Further Description of Step S101.

The on-wafer S parameter measurement system has two ports, i.e., a first port and a second port. In S101, a measurement system is used to measure a thru calibration standard, two load calibration standards, and two pairs of reflect calibration standards. When measuring the thru calibration standard by using the two ports of the measurement system, the measurement reference plane is in the center of the thru calibration standard, i.e., the measurement system is calibrated to the center of the thru calibration standard. In this case, the definition of the thru calibration standard is known, and its definition is the [0,1;1,0] unit matrix. That is, the definition of the thru calibration standard can be obtained without the time and economic cost. The thru calibration standard is a two-port element, and the measured S parameters, that is, the thru S parameters described in S101 include S11, S12, S21 and S22.

For the two load calibration standards that can be called the first load calibration standard and the second load calibration standard, the first load calibration standard can be measured by the first port of the measurement system to obtain a load S parameter S11 and the second load calibration standard can be measured by the second port of the measurement system to obtain a load S parameter S22. That is, the load S parameters in S101 include the load S parameter S11 of the first load calibration standard at the first port of the measurement system and the load S parameter S22 of the second load calibration standard at the second port of the measurement system. The measured impedance of the first load calibration standard at the first port that will be used in the subsequent steps can be calculated out from the load S parameter S11. In the subsequent steps, the actual admittance of the first load calibration standard will also be used. The actual admittance of the first load calibration standard is known because the first load calibration standard is defined. Similarly, the measured impedance of the second load calibration standard can be calculated out from S22, and its actual admittance is known.

The two pair of reflect calibration standards include a pair of open calibration standards and a pair of short calibration standards. The pair of open calibration standards include two identical and symmetrical open calibration standards. Each open calibration standard is a single port element. When measuring the pair of open calibration standards, each of the two ports of the measurement system is connected to one open calibration standard. The first port measures one of the two open calibration standards and obtains an open S parameter S11 and the second port measures the other open calibration standard and obtains an open S parameter S22. The measured impedance of the open calibration standard connected to the first port can be calculated out from the open S parameter S11. The measured impedance of the open calibration standard connected to the second port can be calculated out from the open S parameter S22. The measured impedance of the two open calibration standards will be used in the subsequent steps. The actual admittances of the two open calibration standards will also be used. However, the actual admittances of the two open calibration standards can be cancelled out in calculation process because the two open calibration standards are identical and symmetrical. That is, the actual admittances of the two open calibration standards can be unknown, i.e., the two open calibration standards can be undefined.

Similarly, the pair of short calibration standards include two identical and symmetrical short calibration standards. The first port measures one of the two short calibration standards and obtains a short S parameter S11 and the second port measures the other short calibration standard and obtains a short S parameter S22. The measured impedance of each open calibration standards can be calculated out from its S parameter and will be used in the subsequent steps. The actual admittances of the two short calibration standards can be unknown because they can be cancelled out in calculation process.

In S101, S parameters can be obtained by measuring a thru calibration standard that don't need to define, two defined load calibration standards and two pair of undefined reflect calibration standard. The following steps can obtain eight error terms by using these S parameters and the features of transfer matrix cascade, then perform pre-calibrating based on the eight error terms. It can clearly be seen that, in the process of implementing pre-calibration, only the two load calibration standards need to be defined. Further, based on the pre-calibration, final calibration can be performed. After the final calibration, the on-wafer S parameter measurement system can achieve the expected accuracy and meet the market requirements for commercial on-wafer S parameter calibration systems.

2. Further Description of Step S102.

The eight error terms in S102 include A1, B1, C1, D1, A2, B2, C2 and D2. As shown in FIG. 3, the eight error terms can be expressed in the form of S parameters. Considering that the error network needs to be cascaded in the solution process, the present application represents the error network by the transfer parameters (i.e., A, B, C and D) to facilitate the cascade calculation. There is a one-to-one correspondence between transfer parameters and S parameters which is known in the art. The correspondence between transfer parameters and S parameters can be shown in the following relation (1) and relation (2):

$$[ \begin{matrix}A & B \\ C & D\end{matrix} ] = \frac{1}{2 {S}_{21}} [ \begin{matrix}( 1 + {S}_{11} ) ( 1 - {S}_{22} ) + {S}_{21} {S}_{12} & {Z}_{0} [ ( 1 + {S}_{11} ) ( 1 + {S}_{22} ) - {S}_{21} {S}_{12} ] \\ \frac{1}{{Z}_{0}} [ ( 1 - {S}_{11} ) ( 1 - {S}_{22} ) - {S}_{21} {S}_{12} ] & ( 1 - {S}_{11} ) ( 1 + {S}_{22} ) + {S}_{21} {S}_{12}\end{matrix} ] \qquad ( 1 )$$

$$[ \begin{matrix}{S}_{11} & {S}_{12} \\ {S}_{21} & {S}_{22}\end{matrix} ] = \frac{1}{A + \frac{B}{{Z}_{0}} + C {Z}_{0} + D} [ \begin{matrix}A + \frac{B}{{Z}_{0}} - C {Z}_{0} - D & 2 ( A D - B C ) \\ 2 & - A + \frac{B}{{Z}_{0}} - C {Z}_{0} + D\end{matrix} ] \qquad ( 2 )$$

In the relation (1) and relation (2), S11, S12, S21 and S22 are S parameters; A, B, C and D are transfer parameters; and Zo is characteristic impedance that is known in the art.

Transfer parameters are parameters expressed using voltage and current, as shown in FIG. 4 that shows the relation between the transfer parameters and voltage and current.

S102 can be divided in three sub steps as following:

S1021: calculating the ratio of A1/D1, the ratio of B1/D1 and the ratio of C1/D1 according to the thru S parameters, the load S parameters, the open S parameters, the short S parameters, and the correspondence transfer parameter and S parameter; where A1, B1, C1 and D1 are four error terms corresponding to the first port of the measurement system among the eight error terms.
S1022: performing a first ports swap for the thru S parameters, the load S parameters, the open S parameters and the short S parameters respectively to obtain swapped S parameters; and
S1023: calculating the ratio of A2/D2, the ratio of B2/D2 and the ratio of C2/D2 according to the swapped S parameters, where A2, B2, C2 and D2 are four error terms corresponding to the second port of the measurement system among the eight error terms.

S1021 can be implemented by the following steps:

S1021-1: determining a thru original parameter matrix of the system according to the thru S parameters and the correspondence between transfer parameter and S parameter;
S1021-2: determining a cascade relation according to the thru original parameter matrix; and
S1021-3: calculating the ratio of A1/D1, the ratio of B1/D1 and the ratio of C1/D1 according to the cascade relation, the load S parameters and the reflect S parameters.

In S1021-3, the ratio of A1/D1, the ratio of B1/D1 and the ratio of C1/D1 may be calculated by the following steps:

S1021-31: constructing an admittance relation according to the load S parameters and an actual admittance of the first load calibration standard of the two load calibration standards;
S1021-32: constructing a first error relation according to the cascade relation and the open S parameters;
S1021-33: constructing a second error relation according to the cascade relation and the short S parameters; and
S1021-34: calculating the ratio of A1/D1, the ratio of B1/D1 and the ratio of C1/D1 according to the admittance relation, the first error relation and the second error relation.

The cascade relation determined in S1021-2 is:

E_{T}=E₁E₂ (3)

In the cascade relation (3), E_{T} is the thru original parameter matrix and

$${E}_{T} = [ \begin{matrix}{A}_{T} & {B}_{T} \\ {C}_{T} & {D}_{T}\end{matrix} ] ;$$

E1 is a matrix that contains the four error terms corresponding to the first port of the measurement system and

$${E}_{1} = [ \begin{matrix}{A}_{1} & {B}_{1} \\ {C}_{1} & {D}_{1}\end{matrix} ] = \frac{1}{{D}_{1}} [ \begin{matrix}{A}_{1} / {D}_{1} & {B}_{1} / {D}_{1} \\ {C}_{1} / {D}_{l} & 1\end{matrix} ] ;$$

E2 is a matrix that contains four error terms corresponding to the second port of the measurement system among the eight error terms and

$${E}_{2} = [ \begin{matrix}{A}_{2} & {B}_{2} \\ {C}_{2} & {D}_{2}\end{matrix} ] = \frac{1}{{D}_{2}} [ \begin{matrix}{A}_{2} / {D}_{2} & {B}_{2} / {D}_{2} \\ {C}_{2} / {D}_{2} & 1\end{matrix} ] \cdot \frac{1}{{D}_{1}} [ \begin{matrix}{A}_{1} / {D}_{l} & {B}_{1} / {D}_{1} \\ {C}_{1} / {D}_{1} & 1\end{matrix} ]$$

means E1 normalized to D1 and

$$\frac{1}{{D}_{2}} [ \begin{matrix}{A}_{2} / {D}_{2} & {B}_{2} / {D}_{2} \\ {C}_{2} / {D}_{2} & 1\end{matrix} ]$$

means E2 normalized to D2.

The thru original parameter matrix E_{T} is a transition matrix being from the first port to the second port of the measurement system obtained by measuring the thru calibration standard. As discussed above, there is a one-to-one correspondence between transfer parameters and S parameters. The elements of E_{T}: A_{T}, B_{T}, C_{T}, and D_{T} are transfer parameters and they correspond to the thru S parameters which are known. As discussed above, the thru S parameters are the elements of [0,1;1,0] unit matrix. Therefore, the matrix E_{T} is known. In this case, when the ratio of A1/D1, the ratio of B1/D1, the ratio of C1/D1, the ratio of A2/D2, the ratio of B2/D2, the ratio of C2/D2 and the proportional coefficient D1D2 are calculated out, the eight error terms will be obtained.

Again, the correspondence between transfer parameter and S parameter is:

$${E}_{T} = [ \begin{matrix}{A}_{T} & {B}_{T} \\ {C}_{T} & {D}_{T}\end{matrix} ] = \frac{1}{2 {S}_{21}} [ \begin{matrix}( 1 + {S}_{11} ) ( 1 - {S}_{22} ) + {S}_{21} {S}_{12} & {Z}_{0} [ ( 1 + {S}_{11} ) ( 1 + {S}_{22} ) - {S}_{21} {S}_{12} ] \\ \frac{1}{{Z}_{0}} [ ( 1 - {S}_{11} ) ( 1 - {S}_{22} ) - {S}_{21} {S}_{12} ] & ( 1 - {S}_{11} ) ( 1 + {S}_{22} ) + {S}_{21} {S}_{12}\end{matrix} ] \qquad ( 4 )$$

The admittance relation constructed in S1021-31 is:

$${Y}_{1 , A , load} = \frac{{C}_{1}}{{D}_{1}} \frac{{Z}_{1 , M , load} - \frac{{A}_{1}}{{C}_{1}}}{\frac{{B}_{1}}{{D}_{1}} + {Z}_{1 , M , load}} \qquad ( 5 )$$

In the admittance relation (5), Z_{1,M,load} is the measured impedance of the first load calibration standard at the first port, Z_{1,M,load} can be calculated from the characteristic impedance Z₀ and the first load S parameter of the load S parameters S11, i.e.,

$${Z}_{1 , M , load} = \frac{( 1 + {S}_{11} )}{1 - {S}_{11}} {Z}_{0} ,$$

and Y_{1,A,load} is the actual admittance of the first load calibration standard. As discussed above, Y_{1,A,load} is known because the first load calibration standard is defined. The characteristic impedance Z₀ may be 50Ω.

Optionally,

$${Y}_{1 , A , load} = \frac{1}{{R}_{1} + j ω {L}_{1}} ,$$

where R1 and L1 are the actual resistance and the actual inductance, respectively, of the first load calibration standard at the first port.

The admittance relation of the second load calibration standard at the second port of the measurement system is:

$${Y}_{2 , A , load} = \frac{\frac{{C}_{2}}{{D}_{2}} {Z}_{2 , M , load} + {D}_{2}}{\frac{{B}_{2}}{{D}_{2}} + \frac{{A}_{2}}{{D}_{2}} {Z}_{2 , M , load}} \qquad ( 6 )$$

In the admittance relation (6), Z_{2,M,load} is the measured impedance of the second load calibration standard at the second port, Z_{2,M,load} can be calculated from the characteristic impedance Z₀ and the second load S parameter of the load S parameters S22, i.e.,

$${Z}_{2 , M , load} = \frac{( 1 + {S}_{22} )}{1 - {S}_{22}} {Z}_{0} ,$$

and Y_{2,A,load} is the actual admittance of the second load calibration standard. As discussed above, Y_{2,A,load} is known because the second load calibration standard is defined. The characteristic impedance Z₀ may be 50Ω.

The admittance relation (6) will be used in the process of calculating the ratio of A2/D2, the ratio of B2/D2 and the ratio of C2/D2. The admittance relation (5) is used in the process of calculating the ratio of A1/D1, the ratio of B1/D1 and the ratio of C1/D1.

Optionally,

$${Y}_{2 , A , load} = \frac{1}{{R}_{2} + j ω {L}_{2}} ,$$

where R2 and L2 are the actual resistance and the actual inductance, respectively, of the second load calibration standard at the second port.

The first error relation constructed in S1021-32 is:

$$( {A}_{T} {Z}_{2 , M ( 1 )} - {B}_{T} + {C}_{T} {Z}_{1 , M ( 1 )} - {D}_{T} {Z}_{1 , M ( 1 )} ) ( \frac{{A}_{1}}{{C}_{1}} + \frac{{B}_{1}}{{D}_{1}} ) + ( 2 {D}_{T} - 2 {C}_{T} {Z}_{2 M ( 1 )} ) \frac{{A}_{1} {B}_{1}}{{C}_{1} {D}_{1}} = 2 {A}_{T} {Z}_{1 , M ( 1 )} {Z}_{2 , M ( 1 )} - 2 {B}_{T} {Z}_{1 , M ( 1 )} \qquad ( 7 )$$

In the first error relation (7), Z_{1,M(1)} is the measured impedance of the first open calibration standard (connected to the first port) of the pair of open calibration standards, Z_{1,M(1)} can be calculated based on the first open S parameter of the open S parameters, Z_{2,M(1)} is the measured impedance of the second open calibration standard (connected to the second port) of the pair of open calibration standards and Z_{2,M(1)} can be calculated based on the second open S parameter of the open S parameters. Again, A_{T}, B_{T}, C_{T}, and D_{T} are transfer parameters.

The derivation process of the first error relation (7) is given below. From this derivation, it can be seen how the actual admittance of the two open calibration standards are cancelled out as discussed above.

The following relation can be derived from the cascade relation (3):

$${E}_{2} = {E}_{1}^{- 1} {E}_{T} = \frac{1}{{D}_{1}} \frac{1}{{A}_{1} - {B}_{1} {C}_{1}} ( \begin{matrix}1 & - {B}_{1} \\ - {C}_{1} & {A}_{1}\end{matrix} ) ( \begin{matrix}{A}_{T} & {B}_{T} \\ {C}_{T} & {D}_{T}\end{matrix} ) \qquad ( R - 1 )$$

Further, the following relation can be obtained:

$${A}_{2} = \frac{1}{{D}_{1}} \frac{{A}_{T} - {B}_{1} {C}_{T}}{{A}_{1} - {B}_{1} {C}_{1}} \qquad ( R - 2 )$$

$${B}_{2} = \frac{1}{{D}_{1}} \frac{{B}_{T} - {B}_{1} {D}_{T}}{{A}_{1} - {B}_{1} {C}_{1}} \qquad ( R - 3 )$$

$${C}_{2} = \frac{1}{{D}_{1}} \frac{- {C}_{1} {A}_{T} + {A}_{1} {C}_{T}}{{A}_{1} - {B}_{1} {C}_{1}} \qquad ( R - 4 )$$

$${D}_{2} = \frac{1}{{D}_{1}} \frac{- {C}_{1} {B}_{T} + {A}_{1} {D}_{T}}{{A}_{1} - {B}_{1} {C}_{1}} \qquad ( R - 5 )$$

The actual admittance Y_{1,act} and the measured impedance Z_{1,M(1)} of the first open calibration standard connected to the first port of the measurement system have following relation:

$${Y}_{1 , act} = {C}_{1} \frac{{Z}_{1 , M ( 1 )} - \frac{{A}_{1}}{{C}_{1}}}{{B}_{1} - {Z}_{1 , M ( 1 )}} .$$

The actual admittance Y_{2,act} and the measured impedance Z_{2,M(1)} of the second open calibration standard connected to the second port of the measurement system have following relation:

$${Y}_{2 , act} = \frac{{C}_{2} {Z}_{2 , M ( 1 )} - {D}_{2}}{{B}_{2} - {A}_{2} {Z}_{2 , M ( 1 )}} .$$

Because the two open calibration standards are identical and symmetrical, Y_{1,act}=Y_{2,act}, that is:

$${C}_{1} \frac{{Z}_{1 , M ( 1 )} - \frac{{A}_{1}}{{C}_{1}}}{{B}_{1} - {Z}_{1 , M ( 1 )}} = \frac{{C}_{2} {Z}_{2 , M ( 1 )} - {D}_{2}}{{B}_{2} - {A}_{2} {Z}_{2 , M ( 1 )}} \qquad ( R - 6 )$$

In (R-6), the actual admittances of the two open calibration standards have been cancelled out.

Bring (R-2) to (R-5) into (R-6) and rearrange, the first error relation (7) can be obtained.

Similarly, the second error relation constructed in S1021-32 can be obtained by measuring the pair of short calibration standards. In the derivation process, the actual admittances of the two short calibration standards can be cancelled out. The second error relation is:

$$( {A}_{T} {Z}_{2 , M ( 2 )} - {B}_{T} + {C}_{T} {Z}_{1 , M ( 2 )} - {D}_{T} {Z}_{1 , M ( 2 )} ) ( \frac{{A}_{1}}{{C}_{1}} + \frac{{B}_{1}}{{D}_{1}} ) + ( 2 {D}_{T} - 2 {C}_{T} {Z}_{2 , M ( 2 )} ) \frac{{A}_{1} {B}_{1}}{{C}_{1} {D}_{1}} = 2 {A}_{T} {Z}_{1 , M ( 2 )} {Z}_{2 , M ( 1 )} - 2 {B}_{T} {Z}_{1 , M ( 2 )} \qquad ( 8 )$$

In the second error relation (8), Z_{1,M(2)} is the measured impedance of the first short calibration standard (connected to the first port) of the pair of short calibration standards, Z_{1,M(2)} can be calculated based on the first short S parameter of the short S parameters, Z_{2,M(2)} is the measured impedance of the second short calibration standard (connected to the second port) of the pair of short calibration standards and Z_{2,M(2)} can be calculated based on the second short S parameter of the short S parameters.

Based on the admittance relation (5), the first error relation (7) and the second error relation (8), the ratio of A1/D1, the ratio of B1/D1 and the ratio of C1/D1 can be derived as follows:

For the first error relation (7), set:

x₁=A_{T}Z_{2,M(1)}−B_{T}+C_{T}Z_{1,M(1)}Z_{2,M(2)}−D_{T}Z_{1,M(1)} (A-1)

y₁=2D_{T}−2C_{T}Z_{2,M(1)} (A-2)

v₁=2A_{T}Z_{1,M(1)}Z_{2,M(1)}−2B_{T}Z_{1,M(1)} (A-3)

For the second error relation (7), set:

x₂=A_{T}Z_{2,M(2)}−B_{T}+C_{T}Z_{1,M(2)}Z_{2,M(2)}−D_{T}Z_{1,M(2)} (A-4)

y₂=2D_{T}−2C_{T}Z_{2,M(2)} (A-5)

v₂=2A_{T}Z_{1,M(2)}Z_{2,M(2)}−2B_{T}Z_{1,M(2)} (A-6)

For both the first error relation (7) and the second error relation (8), set:

$${w}_{1} = \frac{{A}_{1}}{{C}_{1}} + \frac{{B}_{1}}{{D}_{1}} \qquad ( A - 7 )$$

$${w}_{2} = \frac{{A}_{1}}{{C}_{1}} \frac{{B}_{1}}{{D}_{1}} \qquad ( A - 8 )$$

Bring (A-1) to (A-8) into the first error relation (7) and the second error relation (8), combining the admittance relation (5), the ratio of A1/D1, the ratio of B1/D1 and the ratio of C1/D1 are obtained:

$$\frac{{B}_{1}}{{D}_{1}} = \frac{{w}_{1} \pm \sqrt{{w}_{1}^{2} - 4 {w}_{2}}}{2} ; \\ \frac{{C}_{1}}{{D}_{1}} = \frac{( \frac{{B}_{1}}{{D}_{1}} - {Z}_{1 , M , load} ) {Y}_{1 , A , load}}{{Z}_{1 , M , load} - \frac{{w}_{1} \pm \sqrt{{w}_{1}^{2} - 4 {w}_{2}}}{2}} ; \\ \frac{{A}_{1}}{{D}_{1}} = \frac{{C}_{1}}{{D}_{1}} \frac{{w}_{1} \pm \sqrt{{w}_{1}^{2} - 4 {w}_{2}}}{2} .$$

In summary, the thru original parameter matrix E_{T} is a transition matrix being from the first port to the second port of the measurement system obtained by measuring the thru calibration standard. Based on E_{T} and the cascade relation (4), the first error relation (7) and the second error relation (8) can be obtained. Based on relation (7) and (8), the ratio of A1/C1 and the ratio of B1/D1 can be obtained. Based on the ratio of A1/C1, the ratio of B1/D1 and the admittance relation (5), the ratio of A1/C1, the ratio of B1/D1 and the ratio of C1/D1 can be obtained. Based on the relationship among the ratio of A1/C1, the ratio of B1/D1 and the ratio of C1/D1, the ratio of A1/D1, the ratio of B1/D1 and the ratio of C1/D1 can be obtained.

The ports swap in S1022 means changing the port corresponding to each S parameter, i.e., changing the first port to the second port of the measurement system and changing the second port to the first port of the measurement system. Performing the ports swap on the thru S parameters obtains swapped thru S parameters. Performing the ports swap on the load S parameters obtains swapped load S parameters. Performing the ports swap on the reflect S parameters obtains swapped reflect S parameters.

Specifically, the ports swap in S1022 includes: swapping S11 and S22 of the load S parameters and the reflect S parameters; and

swapping S11 and S22, S12 and S21 of the thru S parameters.

The thru S parameters before the ports swap can be expressed as

$$[ \begin{matrix}{S}_{11} & {S}_{12} \\ {S}_{21} & {S}_{22}\end{matrix} ] ,$$

then the swapped thru S parameters can be expressed as

$$[ \begin{matrix}{S}_{22} & {S}_{21} \\ {S}_{12} & {S}_{11}\end{matrix} ] .$$

S1023, i.e., calculating the ratio of A2/D2, the ratio of B2/D2 and the ratio of C2/D2 according to the swapped S parameters, comprises:

S1023-1: calculating the ratio of A3/D3, the ratio of B3/D3 and the ratio of C3/D3, by using a method of calculating the ratio of A1/D1, the ratio of B1/D1 and the ratio of C1/D1, according to the swapped S parameters, where A3, B3, C3, D3 are temp error terms;

S1023-2: performing a second ports swap and determining a transition matrix of the second port of the system according to the ratio of A3/D3, the ratio of B3/D3 and the ratio of C3/D3; and

S1023-3: performing a third ports swap and obtaining the ratio of A2/D2, the ratio of B2/D2 and the ratio of C2/D2 according to the transition matrix.

Specifically, the ratio of A2/D2, the ratio of B2/D2 and the ratio of C2/D2 are calculated by the following step 1 to step 3.

Step 1: swapping ports of S parameters, that is: for the reflect S parameters and the load S parameters, set S11 measured by the first port of the measurement system as S22 and set S22 measured by the second port of the measurement system as S11; and for the thru S parameters, set

$$[ \begin{matrix}{S}_{11} & {S}_{12} \\ {S}_{21} & {S}_{22}\end{matrix} ] as [ \begin{matrix}{S}_{22} & {S}_{21} \\ {S}_{12} & {S}_{11}\end{matrix} ] .$$

Step 2: calculating the ratio of A3/D3, the ratio of B3/D3 and the ratio of C3/D3, by using a method of calculating the ratio of A1/D1, the ratio of B1/D1 and the ratio of C1/D1, according to the swapped S parameters, where A3, B3, C3, D3 are temp error terms.

In step 2,

$${E}_{3} = [ \begin{matrix}{A}_{3} & {B}_{3} \\ {C}_{3} & {D}_{3}\end{matrix} ] = \frac{1}{{D}_{3}} [ \begin{matrix}{A}_{3} / {D}_{3} & {B}_{3} / {D}_{3} \\ {C}_{3} / {D}_{3} & 1\end{matrix} ] ,$$

where E3 is equivalent to E2 after the ports are swapped and E3 can solved in the same way as E1 disclosed above.
In step 2, convert transition matrix E3 normalized by D3 into S parameters, as follows:

$$[ \begin{matrix}{S}_{11} & {S}_{12} \\ {S}_{21} & {S}_{22}\end{matrix} ] = [ \begin{matrix}\frac{A + B - C - D}{A + B + C + D} & \frac{2 det ( A )}{A + B + C + D} \\ \frac{2}{A + B + C + D} & \frac{- A + B - C + D}{A + B + C + D}\end{matrix} ] ,$$

where det(*) represents the value of the determinant of *.

Step 3: performing ports swap on the S parameters obtained in step 2 and obtaining the following transition matrix:

$$[ \begin{matrix}A & B \\ C & D\end{matrix} ] = [ \begin{matrix}\frac{1 - det ( S ) + {S}_{11} - {S}_{22}}{2 {S}_{21}} & \frac{1 + det ( S ) + {S}_{11} + {S}_{22}}{2 {S}_{21}} \\ \frac{1 + det ( S ) - {S}_{11} - {S}_{22}}{2 {S}_{21}} & \frac{1 - det ( S ) - {S}_{11} + {S}_{22}}{2 {S}_{21}}\end{matrix} ] .$$

Set the element at the second row and the second column

$$\frac{1 - det ( S ) - {S}_{11} + {S}_{22}}{2 {S}_{21}} = k ,$$

normalize the transition matrix above by D3, obtain:

$${E}_{4} = k [ \begin{matrix}{A}_{2} / {D}_{2} & {B}_{2} / {D}_{2} \\ {C}_{2} / {D}_{2} & 1\end{matrix} ] .$$

Because

$${E}_{2} = [ \begin{matrix}{A}_{2} / {D}_{2} & {B}_{2} / {D}_{2} \\ {C}_{2} / {D}_{2} & 1\end{matrix} ] ,$$

therefore the ratio of A2/D2, the ratio of B2/D2 and the ratio of C2/D2 are obtained.

The definition of transfer matrix is related to the direction of wave transmission, i.e., the wave transmits from the first port to the second port, or the wave transmits from the second port to the first port. Both E1 and E2 in FIG. 3 are obtained when the wave transmits from the first port to the second port, and E2 becomes E3 if the wave transmits from the second port to the first port. Change the transmission direction to from the first port to the second port, E3 becomes E4. E4 and E2 have a proportional relationship, which can be seen as E2=E4 here.

3. Further Description of Step S103.

S103 can be implemented by:

S1031: performing the pre-calibration to the uncalibrated measurement system according to the ratio of A1/D1, the ratio of B1/D1 and the ratio of C1/D obtained in S1021, the ratio of A2/D2, the ratio of B2/D2 and the ratio of C2/D2 obtained in S1022 and the proportional coefficient D1D2.

The calculation process of the proportional coefficient D1D2 is as follows.

The uncalibrated measurement system measures a passive reciprocal element, e.g., the pair of open calibration standards, the pair of short calibration standards or the two load calibration standards. The passive reciprocal element has reciprocity and when it is measured, the following relation can be obtained:

E_{D}_{_{UT}}=E1*E_{A_DUT}*E2 (9)

In the relation (9), E_{DUT} represents the uncorrected measurement result of the DUT (i.e., Device Under Test and it refers to the passive reciprocal element here). E_{A_DUT} represents the actual value of the DUT. Both E_{DUT} and E_{A_DUT} can be expressed by transition matrix whose elements are A, B, C and D.

Because of the reciprocity of the passive reciprocal element, for its S parameters, S21=S12 and the determinant of the corresponding transition matrix of the passive reciprocal element is one. Therefore, the relation (9) can be changed to:

|E_{DUT}|=|E1|*|E2| (10)

The magnitude of D1D2 can be obtained according to the relation (10). The phase of D1D2 can be obtained through the technical means known in the art. For example, with the measured phase of one of the pair of open calibration standards or short calibration standards, the phase of D1D2 can be obtained. So far, both the magnitude and the phase of D1D2 have been obtained, and the proportional coefficient D1D2 has been solved.

S101 to S104 implements the pre-calibration of the measurement system and this process can be summarized as follows:
1) measuring a thru calibration standard, two load calibration standards, two pairs of reflect calibration standards and a passive reciprocal element respectively, by using an uncalibrated on-wafer S parameter measurement system, to obtain the thru original parameter matrix E_{T} and the cascade relation (3);
2) measuring the two load calibration standards by using the uncalibrated system to obtain admittance relations (5) and (6); measuring the pair of open calibration standards to obtain the first error relation (7); measuring the pair of short calibration standards to obtain the second error relation (8); obtaining the ratio of A1/D1, the ratio of B1/D1, and the ratio of C1/D1 according to the relations (4) to (8);
3) swapping the two ports of the measurement system and obtaining swapped S parameters; obtaining the ratio of A3/D3, the ratio of B3/D3, and the ratio of C3/D3 according to the swapped S parameters and by using the same method of solving the ratio of A1/D1, the ratio of B1/D1, and the ratio of C1/D1;
4) determining a transition matrix of the second port after the ports swap according to the ratio of A3/D3, the ratio of B3/D3, and the ratio of C3/D3; based on the transition matrix, perform ports swap again to determine the ratio of A2/D2, the ratio of B2/D2, and the ratio of C2/D2;
5) based on the reciprocity of the passive reciprocal element, obtaining the proportional coefficient D1D2;
6) pre-calibrating the measurement system according to the ratio of A1/D1, the ratio of B1/D1, the ratio of C1/D1, the ratio of A2/D2, the ratio of B2/D2, the ratio of C2/D2 and the proportional coefficient D1D2.

4. Further Description of Step S104.

Crosstalk calibration standard with known properties is selected for simulation, and the S parameters of the crosstalk calibration standard can be obtained. The crosstalk calibration standard may be the pair of open calibration standards. S parameters of the crosstalk calibration standard obtained by simulation can be regarded as the actual S parameters of the crosstalk calibration standard, that is, the real S parameters of the crosstalk calibration standard. The properties of the crosstalk calibration standard include physical properties and material properties such as permittivity, conductivity, permeability and density, etc. The properties of the crosstalk calibration standard also include geometric parameters such as length, width and height. Simulation is generally implemented using simulation software known in the art. The simulation software may be three-dimensional electromagnetic field simulation software, such as CST (Computer Simulation Technology), HFSS (High Frequency Structure Simulator), and the like. After the simulation is completed, a simulation diagram can be obtained, and the real S parameters of the crosstalk calibration standard can be obtained through the simulation diagram.

It is noted that, although S104 can obtain the real S parameters of the crosstalk calibration standard through simulation. However, for any DUT, it is generally impossible to obtain its real S parameters through simulation. Because for any DUT, its physical and material properties are generally unknown, and its structural composition is very complex.

5. Further Description of Step S105.

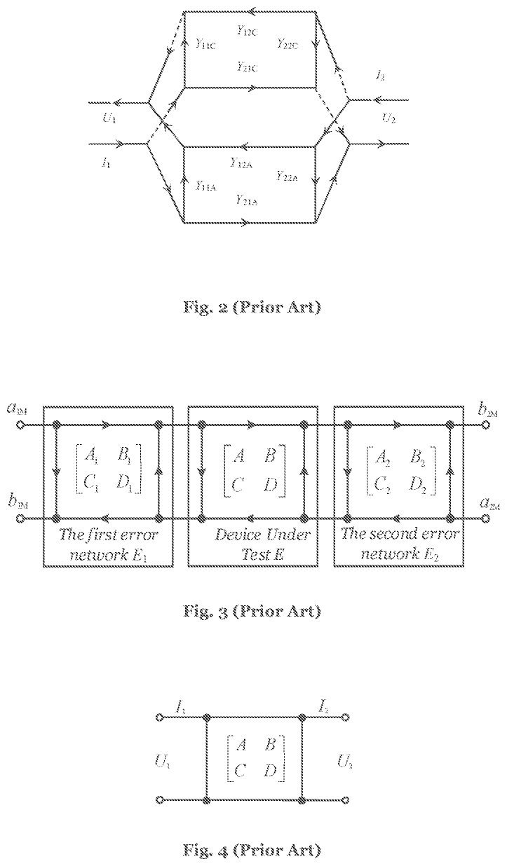

The crosstalk errors of the measurement system can be equivalent to a microwave circuit network shunt in parallel with the DUT (i.e., the crosstalk calibration standard) which is known in the art and shown in FIG. 2. The crosstalk errors obtained in S 105 include the real S parameters of the crosstalk calibration standard and the crosstalk errors. Y_{T} is used to represent the crosstalk S parameters, Y_{C} is used to represent the crosstalk errors of the measurement system, and Y_{A} is used to represent the real S parameters of the crosstalk calibration standard, then Y_{C}=Y_{T}−Y_{A}.

6. Further Description of Step S106.

S106 can be implemented by:

S1061: converting the real S parameters of the crosstalk calibration standard to real Y parameters according to the conversion relationship between Y parameter and S parameter;

S1062: converting the crosstalk S parameters into crosstalk Y parameters according to the conversion relationship;

S1063: calculating the crosstalk errors according to the real Y parameters and the crosstalk Y parameters.

Y parameters and the conversion relationship between Y parameter and S parameter is known in the art.

FIG. 2 shows a crosstalk error model. In FIG. 2, Y_{11A}, Y_{21A}, Y_{12A}, and Y_{22A} represent the real Y parameters of the DUT (e.g., crosstalk calibration standard), and the matrix formed by them is represented by Y_{A}. Y_{11C}, Y_{21C}, Y_{12C}, Y_{22C} represent the crosstalk errors of the measurement system, and its matrix is represented by Y_{C}. Y_{A} and Y_{C} are in parallel relationship, they have the same input and output, have the same voltage U1 and U2, and the current relationship (I1 and I2) is superimposed. Use Y_{T} to represent the crosstalk Y parameters of the crosstalk calibration standard, then Y_{C}=Y_{T}−Y_{A}. The matrices Y_{A} and Y_{C} are as follows:

$${Y}_{A} = ( \begin{matrix}{Y}_{11 A} & {Y}_{12 A} \\ {Y}_{21 A} & {Y}_{22 A}\end{matrix} ) {Y}_{C} = ( \begin{matrix}{Y}_{11 C} & {Y}_{12 C} \\ {Y}_{21 C} & {Y}_{22 C}\end{matrix} ) .$$

For S104 to S106, a plurality of crosstalk calibration standards can be simulated and measured. In this way, each crosstalk calibration standard can correspondingly obtain a group of crosstalk errors of the measurement system. Multiple groups of crosstalk errors can be averaged to measure the final crosstalk errors of the measurement system. By averaging, random errors can be reduced, making the resulting crosstalk errors more accurate.

When the plurality of crosstalk calibration standards are simulated and measured, S104, S105 and S106 change to:

S104-1: performing a simulation to each crosstalk calibration standard to obtain a group of real S parameters of each crosstalk calibration standard;

S105-1: measuring each crosstalk calibration standard in S104-1 by using the pre-calibrated system to obtain a group of crosstalk S parameters of each crosstalk calibration standard;

S106-1: calculating a group of crosstalk errors of the measurement system according to one group of real S parameters obtained in S104-1, one group of crosstalk S parameters obtained in S105-1 and the conversion relationship between Y parameter and S parameter; and

averaging the multiple groups of crosstalk errors to obtain a final group of crosstalk errors as the measured crosstalk errors of the measurement system.

7. Further Description of Step S107.

After obtaining the crosstalk errors Y_{C} of the measurement system, any DUT can be measured to obtain the S parameters of the DUT. Convert the S parameters to Y parameters, denoted as Y_{T}^{DUT}. Then the real Y matrix Y_{DUT} of the DUT is: Y^{DUT}=Y_{T}^{DUT}−Y_{C}. After the real Y matrix of the DUT is obtained, according to the conversion relationship between the Y parameter and S parameter, the real S parameters of the DUT can finally be obtained, and the calibration of the S parameters of the DUT can be realized.

That is, the process of final-calibration in S107 is actually implemented in each measurement process. After measuring the crosstalk Y parameters of the DUT, subtract the crosstalk errors Y_{C} from the crosstalk Y parameters, then convert the result into S parameters, and the real S parameter of the DUT are obtained finally.

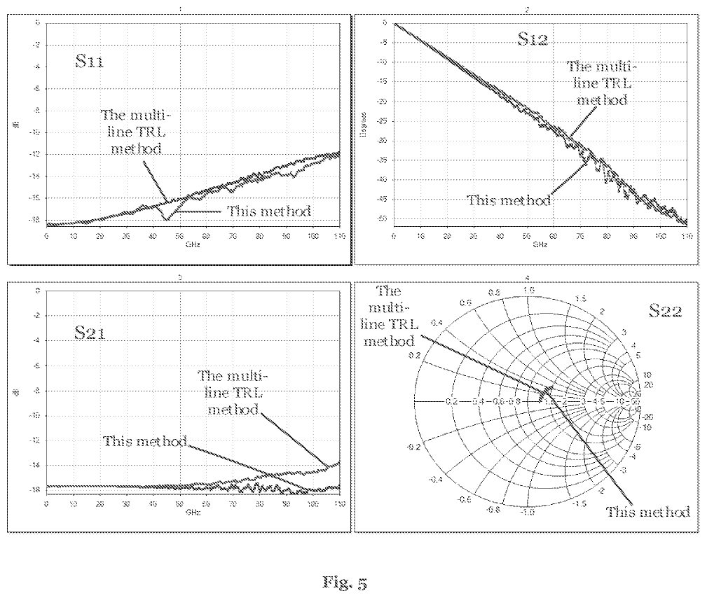

To examine the calibration accuracy of the method provided by the present application, the method provided by the present application is compared with the multi-line TRL (Thru-Reflect-Line) method which is provided by National Institute of Standards and Technology and is recognized in the art as having the highest calibration accuracy. In the 100 MHz-110 GHz frequency band, the same on-wafer S parameter measurement system is calibrated by using the method provided by the present application and the multi-line TRL method, respectively. Then measure the same on-wafer attenuator by using the calibrated system and obtain two groups of measurement results. Compare the two group of measurements results and FIG. 5 shows the comparison result. Compared with the multi-line TRL method, the measurement result corresponding to the method provided by the present improves S11 by 0.02 and improves S21 by 1.7 dB at most. This means the calibration method provided by the present application is reasonable and can meet the requirements of on-wafer S-parameter calibration and measuring.

The calibration method provided by the present application only uses two pairs of symmetrical undefined reflection calibration standards, an undefined thru calibration standard and two defined load calibration standards, to realize the calibration of the measurement system. Considering the leakage error of microwave probes in millimeter-wave and above on-wafer systems, a circuit to characterize leakage is added to the single-port load calibration standard circuit model.

The calibration method provided in this application can be divided into two parts.

The first part is the pre-correction process. First, the basic eight-term error model is obtained, that is, the six basic error terms of the on-wafer leakage system are calculated respectively by using the ABCD matrix through two pairs of reflect calibration standards and a pair of load calibration standards. Then measure an undefined two-port passive element (e.g., the reflect calibration standards or the load calibration standards or other passive elements) and use their reciprocity properties to get the residual error terms;

In the second part, the crosstalk errors of the measurement system are calculated by using the parallel crosstalk error model in the prior art. The solution algorithm is verified. A calibration kit and a passive attenuator verification element with a 110 GHz ceramic substrate were developed. Compared with the commercial calibration methods in the prior art, the measurement result of the verification part S11 was improved by 0.02, and the test result of S21 was optimized by 1.7 dB at most. Defined information requirements are less. Compared with the SOLR calibration method in the prior art, the calibration method in this application can be achieved without accurately knowing the exact values of the two pairs of on-wafer reflect calibration standards. Furthermore, if the processing technology is consistent, the calibration method provided by the present application can save a pair of on-wafer reflect calibration standard. The method provided in this application improves the calibration accuracy, improves the calibration efficiency, and reduces the calibration cost.

It should be understood that the size of the sequence numbers of the steps in the above description does not mean the sequence of execution, and the execution sequence of each process should be determined by its function and internal logic, and should not constitute any limitation to the implementation process of the present application.

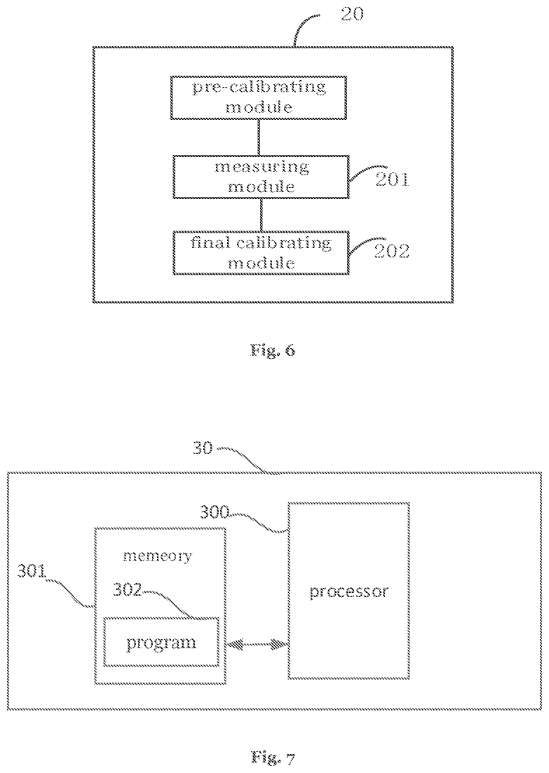

FIG. 6 is a schematic structural diagram of a calibrating device for on-wafer S parameter measurement system provided by the present application. For the convenience of description, only the part related to the present application is shown, and the detailed description is as follows. For details not described in detail therein, reference may be made to the above description of the calibration method.

As shown in FIG. 6, the calibrating device 20 includes pre-calibrating module, measuring module 201 and final calibrating module 202.

The pre-calibrating module includes parameter obtaining unit, error calculating unit.

The parameter obtaining unit can perform S101, i.e., measuring a thru calibration standard, two load calibration standards, two pairs of reflect calibration standards and a passive reciprocal element respectively, by using an uncalibrated on-wafer S parameter measurement system, to obtain thru S parameters, load parameters, reflect parameters and a proportional coefficient.

The error calculating unit can perform S102 and S103, i.e., calculating eight error terms of the uncalibrated measurement system according to the thru S parameters, the load S parameters, the reflect S parameters, the proportional coefficient and a correspondence between transfer parameter and S parameter, and performing a pre-calibration to the uncalibrated measurement system according to the eight error terms to obtain a pre-calibrated system.

The eight error terms of the uncalibrated measurement system include A1, B1, C1, D1, A2, B2, C2 and D2. The error calculating module may include a first calculating unit and a second calculating unit.

The first calculating unit can perform the S1021 to S1023, i.e.:

S1021: calculating the ratio of A1/D1, the ratio of B1/D1 and the ratio of C1/D1 according to the thru S parameters, the load S parameters, the open S parameters, the short S parameters, and the correspondence transfer parameter and S parameter;

S1022: performing a first ports swap for the thru S parameters, the load S parameters, the open S parameters and the short S parameters respectively to obtain swapped S parameters; and

S1023: calculating the ratio of A2/D2, the ratio of B2/D2 and the ratio of C2/D2 according to the swapped S parameters.

The first calculating unit can also perform the S1021-1 to S1021-3, i.e.:

S1021-1: determining a thru original parameter matrix of the system according to the thru S parameters and the correspondence between transfer parameter and S parameter;

S1021-2: determining a cascade relation according to the thru original parameter matrix; and

S1021-3: calculating the ratio of A1/D1, the ratio of B1/D1 and the ratio of C1/D1 according to the cascade relation, the load S parameters and the reflect S parameters.

The second calculating unit can perform the S1031, i.e., performing the pre-calibration to the uncalibrated measurement system according to the ratio of A1/D1, the ratio of B1/D1 and the ratio of C1/D obtained in S1021, the ratio of A2/D2, the ratio of B2/D2 and the ratio of C2/D2 obtained in S1022 and the proportional coefficient D1D2.

The measuring module 201 can perform the S104 and S105, i.e., performing a simulation to a crosstalk calibration standard to obtain real S parameters of the crosstalk calibration standard, and measuring the crosstalk calibration standard by using the pre-calibrated system to obtain crosstalk S parameters, where the crosstalk S parameters contains crosstalk errors of the measurement system and the crosstalk errors can be equivalent to a microwave circuit network in parallel with the crosstalk calibration standard.

The final calibrating module 202 can perform the S106 and S107, i.e., calculating the crosstalk errors of the measurement system according to the real S parameters, the crosstalk S parameters and the conversion relationship between Y parameter and S parameter, and performing a final-calibration to the measurement system according to the crosstalk errors.

The final calibrating module 202 may include a first converting unit, a second converting unit and a crosstalk calculating unit.

The first converting unit can perform the S1061, i.e., converting the real S parameters of the crosstalk calibration standard to real Y parameters according to the conversion relationship between Y parameter and S parameter.

The second converting unit can perform the S1062, i.e., converting the crosstalk S parameters into crosstalk Y parameters according to the conversion relationship.

The crosstalk calculating unit can perform the S1063, i.e., calculating the crosstalk errors according to the real Y parameters and the crosstalk Y parameters.

When a plurality of crosstalk calibration standards are simulated and measured, the final calibrating module 202 may include a simulating unit and a measuring unit.

The simulating unit can perform the S104-1, i.e., performing a simulation to each crosstalk calibration standard to obtain a group of real S parameters of each crosstalk calibration standard.

The measuring unit can perform the S105-1, i.e., measuring each crosstalk calibration standard by using the pre-calibrated system to obtain a group of crosstalk S parameters of each crosstalk calibration standard.

When the plurality of crosstalk calibration standards are simulated and measured, the calibrating device 20 further includes a third calculating unit and a fourth calculating unit.

The third calculating unit can perform the S106-1, i.e., calculating a group of crosstalk errors of the measurement system according to one group of real S parameters, one group of crosstalk S parameters and the conversion relationship between Y parameter and S parameter.

The fourth calculating unit can perform: averaging the multiple groups of crosstalk errors to obtain a final group of crosstalk errors as the measured crosstalk errors of the measurement system and performing a final calibration on the measurement system.

FIG. 7 is a schematic structural diagram of the electronic device provided by the present application. As shown in FIG. 7, the electronic device 30 includes a non-transitory memory 301 storing a computer executable program 302 and a processor 300 to execute the program 302. When the processor 300 executes the program 302, the steps in the above-mentioned embodiments of the method for calibrating crosstalk errors in a system for measuring on-wafer S parameters, for example, steps S101 to S107 shown in FIG. 1, are implemented. Alternatively, when the processor 300 executes the program 302, the functions of the modules in each of the foregoing calibrating device embodiments, such as the functions of the modules 201 and 202 shown in FIG. 6.

Exemplarily, the program 302 may be divided into one or more modules/units, and the one or more modules/units are stored in the memory 301 and executed by the processor 300 to implement the present application. The one or more modules/units may be a series of computer program instruction segments capable of performing specific functions, and the instruction segments are used to describe the execution process of the program 302 in the calibrating device 20. For example, the program 302 can be divided into modules 201 and 202 shown in FIG. 6.

The electronic device 30 may be a computing device such as a desktop computer, a notebook, a handheld computer, and a cloud server. The electronic device 30 may include, but is not limited to, a processor 300 and a memory 301. Those skilled in the art can understand that FIG. 7 is only an example of the electronic device 30, and does not constitute a limitation on the electronic device 30. The electronic device 30 may include more or less components than shown, or some components may be combined, or different components, for example, the electronic device 30 may also include input and output devices, network access devices, buses, and the like.

The processor 300 may be a central processing unit (CPU), and may also be other general-purpose processors, digital signal processors (DSP), application specific integrated circuits (ASIC), Field-Programmable Gate Array (FPGA) or other programmable logic devices, discrete gate or transistor logic devices, discrete hardware components, etc. The general-purpose processor may be a microprocessor or any conventional processor or the like.

The memory 301 may be an internal storage unit of the electronic device 30, such as a hard disk or a memory of the electronic device 30. The memory 301 may also be an external storage device of the electronic device 30, such as a plug-in hard disk, a smart memory card (SMC), a secure digital card (SD) equipped on the electronic device 30, flash card, etc. Further, the memory 301 may also include both an internal storage unit of the electronic device 30 and an external storage device. The memory 301 is used to store the computer program and other programs and data required by the control device. The memory 301 can also be used to temporarily store data that has been output or will be output.

Those skilled in the art can clearly understand that, for the convenience and brevity of description, only the division of the above-mentioned functional units and modules is used as an example for illustration. In practical applications, the above-mentioned function allocation can be completed by different functional units and modules as required, that is, the internal structure of the device is divided into different functional units or modules to complete all or part of the functions described above. Each functional unit and module in the embodiments may be integrated into one processing unit, or each unit may exist physically alone, or two or more units may be integrated into one unit. The above-mentioned integrated units may be implemented in the form of hardware, or may be implemented in the form of software functional units. In addition, the specific names of the functional units and modules are only for the convenience of distinguishing from each other, and are not used to limit the protection scope of the present application. For the specific working process of the units and modules in the above-mentioned device, reference may be made to the corresponding process in the foregoing method embodiments, which will not be repeated here.

In the above-mentioned embodiments, the description of each embodiment has its own emphasis. For parts that are not described or described in detail in a certain embodiment, reference may be made to the relevant descriptions of other embodiments.

Those of ordinary skill in the art can realize that the units and algorithm steps of each example described in conjunction with the embodiments disclosed herein can be implemented in electronic hardware, or a combination of computer software and electronic hardware. Whether these functions are performed in hardware or software depends on the specific application and design constraints of the technical solution. Skilled artisans may implement the described functionality using different methods for each particular application, but such implementations should not be considered beyond the scope of this application.

In the embodiments provided in this application, it should be understood that the disclosed apparatus/control apparatus and method may be implemented in other manners. For example, the device/control device embodiments described above are merely illustrative. For example, the division of the modules or units is only a logical function division, and there may be other division methods in actual implementation. For example, multiple units or components may be combined or may be integrated into another system, or some features may be omitted, or not implemented. On the other hand, the shown or discussed mutual coupling or direct coupling or communication connection may be through some interfaces, indirect coupling or communication connection of devices or units, and may be in electrical, mechanical or other forms.

The units described as separate parts may or may not be physically separate. A component shown as a unit may or may not be a physical unit, it may be located in one place, or it may be distributed over a number of network elements. Some or all of the units may be selected according to actual needs to achieve the purpose of the solution in this embodiment.

In addition, each functional unit in each embodiment of the present application may be integrated into one processing unit, or each unit may exist physically alone, or two or more units may be integrated into one unit. The above-mentioned integrated units may be implemented in the form of hardware, or may be implemented in the form of software functional units.

The integrated modules/units, if implemented in the form of software functional units and sold or used as independent products, may be stored in a computer-readable storage medium. Based on this understanding, the present application can implement all or part of the processes in the methods of the above embodiments, and can also be completed by instructing relevant hardware through a computer program. The computer program can be stored in a computer-readable storage medium, and when executed by the processor, the computer program can implement the steps of the above-mentioned embodiments of the method for calibrating crosstalk errors in a system for measuring on-wafer S parameters. Where, the computer program includes computer program code, and the computer program code may be in the form of source code, object code, executable file or some intermediate form, and the like. The computer-readable medium may include: any entity or device capable of carrying the computer program code, a recording medium, a U disk, a removable hard disk, a magnetic disk, an optical disk, a computer memory, a read-only memory (ROM), Random Access Memory (RAM), electric carrier signal, telecommunication signal and software distribution medium, etc. It should be noted that the content contained in the computer-readable media may be appropriately increased or decreased according to the requirements of legislation and patent practice in the jurisdiction, for example, in some jurisdictions, according to legislation and patent practice, the computer-readable media Excluded are electrical carrier signals and telecommunication signals.

The above-mentioned embodiments are only used to illustrate the technical solutions of the present application, but not to limit them. Although the present application has been described in detail with reference to the above-mentioned embodiments, those of ordinary skill in the art should understand that the technical solutions described in the foregoing embodiments can still be modified, or some technical features thereof can be equivalently replaced. However, these modifications or replacements do not make the essence of the corresponding technical solutions deviate from the spirit and scope of the technical solutions of the embodiments of the present application, and should be included within the protection scope of the present application.

What is claimed is:

1. A method for calibrating crosstalk errors in a system for measuring on-wafer S parameters, comprising:
a first measuring step comprising:
measuring a thru calibration standard using the system for measuring on-wafer S parameters to obtain thru S parameters of the thru calibration standard, wherein a calibration reference plane of the system is calibrated to a center of the thru calibration standard;
measuring two load calibration standards using the system to obtain load S parameters of the two load calibration standards;
measuring a pair of open calibration standards using the system to obtain open S parameters of the pair of open calibration standards, wherein the pair of open calibration standards are undefined and identical;
measuring a pair of short calibration standards using the system to obtain short S parameters of the pair of short calibration standards, wherein the pair of short calibration standards are undefined and identical; and
measuring a passive reciprocal element using the system to obtain a proportional coefficient;
a first calculating step comprising: calculating eight error terms of the system according to the thru S parameters, the load S parameters, the open S parameters, the short S parameters, the proportional coefficient and a correspondence between a transfer parameter and an S parameter;
a first calibrating step comprising: performing a pre-calibration on the system according to the eight error terms to obtain a pre-calibrated system;
a simulating step comprising: performing a simulation of a crosstalk calibration standard to obtain real S parameters of the crosstalk calibration standard;
a second measuring step comprising: measuring the crosstalk calibration standard using the pre-calibrated system to obtain crosstalk S parameters of the crosstalk calibration standard, wherein the crosstalk S parameters comprises crosstalk errors of the system;
a second calculating step comprising: calculating the crosstalk errors of the system according to the real S parameters, the crosstalk S parameters and a conversion relationship between a Y parameter and an S parameter; and
a second calibrating step comprising: performing a final-calibration on the system according to the crosstalk errors.

2. The method according to claim 1, wherein the first calculating step further comprises a first sub step, the first sub step comprising: calculating a ratio of A1/D1, a ratio of B1/D1 and a ratio of C1/D1 according to the thru S parameters, the load S parameters, the open S parameters, the short S parameters and the correspondence, wherein A1, B1, C1 and D1 are four error terms corresponding to a first port of the system among the eight error terms.

3. The method according to claim 2, wherein the first sub step further comprises:
determining a thru original parameter matrix of the system according to the thru S parameters and the correspondence;
determining a cascade relation according to the thru original parameter matrix; and
calculating the ratio of A1/D1, the ratio of B1/D1 and the ratio of C1/D1 according to the cascade relation, the load S parameters, the open S parameters and the short S parameters.

4. The method according to claim 3, wherein the cascade relation is E_{T}=E₁E₂, wherein:
E_{T} is the thru original parameter matrix and
$${E}_{T} = [ \begin{matrix}{A}_{T} & {B}_{T} \\ {C}_{T} & {D}_{T}\end{matrix} ] ;$$
E1 is a matrix that includes the four error terms corresponding to the first port of the system and
$${E}_{1} = [ \begin{matrix}{A}_{1} & {B}_{1} \\ {C}_{1} & {D}_{1}\end{matrix} ] = \frac{1}{{D}_{1}} [ \begin{matrix}{A}_{1} / {D}_{1} & {B}_{1} / {D}_{1} \\ {C}_{1} / {D}_{1} & 1\end{matrix} ] ;$$
and
E2 is a matrix that includes four error terms corresponding to a second port of the system among the eight error terms and
$${E}_{2} = [ \begin{matrix}{A}_{2} & {B}_{2} \\ {C}_{2} & {D}_{2}\end{matrix} ] = \frac{1}{{D}_{2}} [ \begin{matrix}{A}_{2} / {D}_{2} & {B}_{2} / {D}_{2} \\ {C}_{2} / {D}_{2} & 1\end{matrix} ] .$$

5. The method according to claim 4, wherein the ratio of A1/D1, the ratio of B1/D1 and the ratio of C1/D1 are calculated using following steps:
constructing an admittance relation according to the load S parameters and an actual admittance of a first load calibration standard of the two load calibration standards;
constructing a first error relation according to the cascade relation and the open S parameters;
constructing a second error relation according to the cascade relation and the short S parameters; and
calculating the ratio of A1/D1, the ratio of B1/D1 and the ratio of C1/D1 according to the admittance relation, the first error relation and the second error relation.

6. The method according to claim 5, wherein the admittance relation is
$${Y}_{1 , A , load} = \frac{{C}_{1}}{{D}_{1}} \frac{{Z}_{1 , M , load} - \frac{{A}_{1}}{{C}_{1}}}{\frac{{B}_{1}}{{D}_{1}} + {Z}_{1 , M , load}} ,$$
wherein Z_{1,M,load} is a measured impedance of the first load calibration standard, Z_{1,M,load} is based on a characteristic impedance Z₀ and a first load S parameter S11 of the load S parameters,
$${Z}_{1 , M , load} = \frac{( 1 + {S}_{11} )}{1 - {S}_{11}} {Z}_{0} ,$$
and Y_{1,A,load} is the actual admittance of the first load calibration standard.

7. The method according to claim 5, wherein the first error relation is representable as:
$$( {A}_{T} {Z}_{2 , M ( 1 )} - {B}_{T} + {C}_{T} {Z}_{1 , M ( 1 )} - {D}_{T} {Z}_{1 , M ( 1 )} ) ( \frac{{A}_{1}}{{C}_{1}} + \frac{{B}_{1}}{{D}_{1}} ) + ( 2 {D}_{T} - 2 {C}_{T} {Z}_{2 , M ( 1 )} ) \frac{{A}_{1} {B}_{1}}{{C}_{1} {D}_{1}} = 2 {A}_{T} {Z}_{1 , M ( 1 )} {Z}_{2 , M ( 1 )} - 2 {B}_{T} {Z}_{1 , M ( 1 )} ,$$
wherein Z_{1,M(1)} is a measured impedance of a first open calibration standard of the pair of open calibration standards, Z_{1,M(1)} is based on a first open S parameter of the open S parameters, Z_{2,M(1)} is a measured impedance of a second open calibration standard of the pair of open calibration standards and Z_{2,M(1)} is based on a second open S parameter of the open S parameters, and A_{T}, B_{T}, C_{T}, and D_{T} are transfer parameters.

8. The method according to claim 5, wherein the second error relation is representable as:
$$( {A}_{T} {Z}_{2 , M ( 2 )} - {B}_{T} + {C}_{T} {Z}_{1 , M ( 2 )} - {D}_{T} {Z}_{1 , M ( 2 )} ) ( \frac{{A}_{1}}{{C}_{1}} + \frac{{B}_{1}}{{D}_{1}} ) + ( 2 {D}_{T} - 2 {C}_{T} {Z}_{2 , M ( 2 )} ) \frac{{A}_{1} {B}_{1}}{{C}_{1} {D}_{1}} = 2 {A}_{T} {Z}_{1 , M ( 2 )} {Z}_{2 , M ( 1 )} - 2 {B}_{T} {Z}_{1 , M ( 2 )} ,$$
wherein Z_{1,M(2)} is a measured impedance of a first short calibration standard of the pair of short calibration standards, Z_{1,M(2)} is based on a first short S parameter of the short S parameters, Z_{2,M(2)} is a measured impedance of a second short calibration standard of the pair of short calibration standards and Z_{2,M(2)} is based on a second short S parameter of the short S parameters, and A_{T}, B_{T}, C_{T}, and D_{T} are transfer parameters.

9. The method according to claim 2, wherein the first calculating step further comprises a second sub step, and the second sub step comprises:
performing a first ports swap for the thru S parameters, the load S parameters, the open S parameters and the short S parameters, respectively, to obtain swapped S parameters; and
calculating a ratio of A2/D2, a ratio of B2/D2 and a ratio of C2/D2 according to the swapped S parameters, wherein A2, B2, C2 and D2 are four error terms corresponding to a second port of the system among the eight error terms.

10. The method according to claim 9, wherein performing the first ports swap comprises:
swapping S11 and S22 of the load S parameters, the open S parameters and the short S parameters; and
swapping S11 and S22, S12 and S21, respectively, of the thru S parameters.

11. The method according to claim 9, wherein the second sub step further comprises:
calculating a ratio of A3/D3, a ratio of B3/D3 and a ratio of C3/D3, using a method of calculating A1/D1, B1/D1 and C1/D1, according to the swapped S parameters, wherein A3, B3, C3, D3 are temp error terms;
performing a second ports swap and determining a transition matrix of the second port of the system according to the ratio of A3/D3, the ratio of B3/D3 and the ratio of C3/D3; and
performing a third ports swap and obtaining the ratio of A2/D2, the ratio of B2/D2 and the ratio of C2/D2 according to the transition matrix.

12. The method according to claim 1, wherein the second calculating step further comprises:
converting the real S parameters of the crosstalk calibration standard to real Y parameters according to the conversion relationship;
converting the crosstalk S parameters to crosstalk Y parameters according to the conversion relationship; and
calculating the crosstalk errors according to the real Y parameters and the crosstalk Y parameters.

13. The method according to claim 12, wherein the crosstalk errors are elements of a matrix Y1, the real Y parameters are elements of a matrix Y2, the crosstalk Y parameters are elements of a matrix Y3, and Y1=Y3−Y2.

14. An electronic device comprising
a non-transitory memory storing a computer executable program; and
a processor, configured to execute the program to implement a method for calibrating crosstalk errors in a system for measuring on-wafer S parameters, wherein the method comprises:
a first measuring step, comprising:
measuring a thru calibration standard using the system for measuring on-wafer S parameters to obtain thru S parameters of the thru calibration standard, wherein a calibration reference plane of the system is calibrated to a center of the thru calibration standard;
measuring two load calibration standards using the system to obtain load S parameters of the two load calibration standards;
measuring a pair of open calibration standards using the system to obtain open S parameters of the pair of open calibration standards, wherein the pair of open calibration standards are undefined and identical;
measuring a pair of short calibration standards using the system to obtain short S parameters of the pair of short calibration standards, wherein the pair of short calibration standards are undefined and identical; and
measuring a passive reciprocal element by using the system to obtain a proportional coefficient;
a first calculating step comprising: calculating eight error terms of the system according to the thru S parameters, the load S parameters, the open S parameters, the short S parameters, the proportional coefficient and a correspondence between a transfer parameter and an S parameter;
a first calibrating step comprising: performing a pre-calibration on the system according to the eight error terms to obtain a pre-calibrated system;
a simulating step comprising: performing a simulation of a crosstalk calibration standard to obtain real S parameters of the crosstalk calibration standard;
a second measuring step comprising: measuring the crosstalk calibration standard using the pre-calibrated system to obtain crosstalk S parameters of the crosstalk calibration standard, wherein the crosstalk S parameters comprises crosstalk errors of the system;
a second calculating step comprising: calculating the crosstalk errors of the system according to the real S parameters, the crosstalk S parameters and a conversion relationship between a Y parameter and an S parameter; and
a second calibrating step comprising: performing a final-calibration to the system according to the crosstalk errors.

15. A non-transitory computer readable storage medium storing a computer executable program, wherein when the computer executable program is executed by a processor, a method for calibrating crosstalk errors in a system for measuring on-wafer S parameters is implemented, wherein the method comprises:
a first measuring step, comprising:
measuring a thru calibration standard using the system for measuring on-wafer S parameters to obtain thru S parameters of the thru calibration standard, wherein a calibration reference plane of the system is calibrated to a center of the thru calibration standard;
measuring two load calibration standards using the system to obtain load S parameters of the two load calibration standards;
measuring a pair of open calibration standards using the system to obtain open S parameters of the pair of open calibration standards, wherein the pair of open calibration standards are undefined and identical;
measuring a pair of short calibration standards using the system to obtain short S parameters of the pair of short calibration standards, wherein the pair of short calibration standards are undefined and identical; and
measuring a passive reciprocal element using the system to obtain a proportional coefficient;
a first calculating step comprising: calculating eight error terms of the system according to the thru S parameters, the load S parameters, the open S parameters, the short S parameters, the proportional coefficient and a correspondence between a transfer parameter and an S parameter;
a first calibrating step comprising: performing a pre-calibration on the system according to the eight error terms to obtain a pre-calibrated system;
a simulating step comprising: performing a simulation of a crosstalk calibration standard to obtain real S parameters of the crosstalk calibration standard;
a second measuring step comprising: measuring the crosstalk calibration standard by using the pre-calibrated system to obtain crosstalk S parameters of the crosstalk calibration standard, wherein the crosstalk S parameters comprises crosstalk errors of the system;
a second calculating step comprising: calculating the crosstalk errors of the system according to the real S parameters, the crosstalk S parameters and a conversion relationship between a Y parameter and an S parameter; and
a second calibrating step comprising: performing a final-calibration on the system according to the crosstalk errors.
